(19) United States
(12) Patent Application Publication
(10) Pub. No.: US 2011/0162690 A1
(43) Pub. Date: Jul. 7, 2011

(54) TRANSPORTABLE SOLAR PANEL AND SUPPORT SYSTEM

(75) Inventors: Robert Emmett Workman, Morgan, UT (US); Norm Krantz, Logan, UT (US)

(73) Assignee: Goal Zero LLC

(21) Appl. No.: 12/983,677

(22) Filed: Jan. 3, 2011

Related U.S. Application Data
(60) Provisional application No. 61/335,463, filed on Jan. 6, 2010.

(51) Int. Cl. H01L 31/045; H01L 31/18

(52) U.S. Cl. 136/245; 29/890.033

(57) ABSTRACT

A transportable solar panel and support system has a flexible base, and a plurality of photovoltaic solar panels coupled to the flexible base. The solar panels are spaced apart from one another by gaps to permit the flexible base to be configured in an unfolded condition so that the solar panels can receive sunlight, and a folded condition where the solar panels are arranged at least partially adjacent to one another. A storage compartment and receptacles are disposed on the flexible base, with at least a portion of the receptacles axially aligned with one another to span one or more of the gaps between the solar panels. Support rods are provided that are movable between a stowed position within the storage compartment when the flexible base is in the folded condition, and a deployed position within the receptacles and spanning one or more of the gaps between the solar panels when the flexible base is in the unfolded condition.

### CROSS-REFERENCE TO RELATED APPLICATIONS

This patent application claims the benefit of priority under 35 U.S.C. §119(e) of U.S. Provisional Application No. 61/335,463, having a filing date of Jan. 6, 2010, titled “Foldable Solar Panel Support System,” the complete disclosure of which is hereby incorporated by reference.

### FIELD

The present invention relates generally to the field of transportable solar panels and more specifically it relates to a foldable solar panel and support system.

### BACKGROUND

This section is intended to provide a background or context to the invention recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Certain types of foldable solar panels are generally known, and are typically made of several fairly rigid solar cells sewn or attached to fabric allowing them to be folded (e.g. much like a map). These devices are intended to be portable for things such as camping or other “away from the grid” activities. As such a user is never certain what means will be available at the desired destination to “set up” the device upon.

One purpose of the invention is to provide a system for supporting a transportable (e.g. foldable or flexible, etc.) solar panel and to allow a user to prop or otherwise support the foldable solar panel quickly and conveniently, without the use of large or cumbersome stands or other parts, and to allow folding for lightweight and compact portability and also to more efficiently receive sunlight.

Accordingly, it would be desirable to provide a transportable photovoltaic solar panel and support system that overcomes the disadvantages of the conventional systems.

### SUMMARY

One embodiment of the invention relates to a transportable solar panel and support system having a sheet of flexible material with a first side and a second side. A plurality of photovoltaic solar panels are coupled to the first side of the sheet of flexible material, with the solar panels spaced apart from one another by gaps to permit the sheet of flexible material to be configured in an unfolded condition so that the solar panels can receive sunlight, and a folded condition where the solar panels are stacked adjacent one another for transport. A storage compartment is disposed on the sheet of flexible material, and a plurality of receptacles are disposed on the second side of the sheet of flexible material, with at least a portion of the receptacles axially aligned with one another to span one or more of the gaps between the solar panels. A plurality of support members are disposed within the storage compartment when the sheet of flexible material is in the folded condition, and are disposed within the receptacles and span one or more of the gaps between the solar panels when the sheet of flexible material is in the unfolded condition.

Another embodiment of the invention relates to a transportable solar panel and support system having a flexible base, and a plurality of photovoltaic solar panels coupled to the flexible base. The solar panels are spaced apart from one another by gaps to permit the flexible base to be configured in an unfolded condition so that the solar panels can receive sunlight, and a folded condition where the solar panels are arranged at least partially adjacent to one another. A storage compartment and a plurality of receptacles are disposed on the flexible base, with at least a portion of the receptacles axially aligned with one another to span one or more of the gaps between the solar panels. A plurality of support rods are provided that are movable between a stowed position within the storage compartment when the flexible base is in the folded condition, and a deployed position within the receptacles and spanning one or more of the gaps between the solar panels when the flexible base is in the unfolded condition.

A further embodiment of the invention relates to a method of providing a transportable solar panel and support system, and includes the steps of providing a flexible base, and coupling a plurality of photovoltaic solar panels to the flexible base, and spacing the solar panels apart from one another by gaps to permit the flexible base to be unfolded so that the solar panels can receive sunlight, and folded where the solar panels are arranged at least partially adjacent to one another, and coupling a storage compartment to the flexible base, and providing a plurality of receptacles on the flexible base, at least a portion of the receptacles axially aligned with one another to span one or more of the gaps between the solar panels, and providing a plurality of support rods, the support rods being movable between a stowed position within the storage compartment when the flexible base is folded, and a deployed position within the receptacles and spanning one or more of the gaps between the solar panels when the flexible base is unfolded.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a schematic representation of a rear view of the transportable solar panel and support system in operation, and showing its general features including the rods being fastened to fabric or material on the opposite side of solar panels, according to an exemplary embodiment.

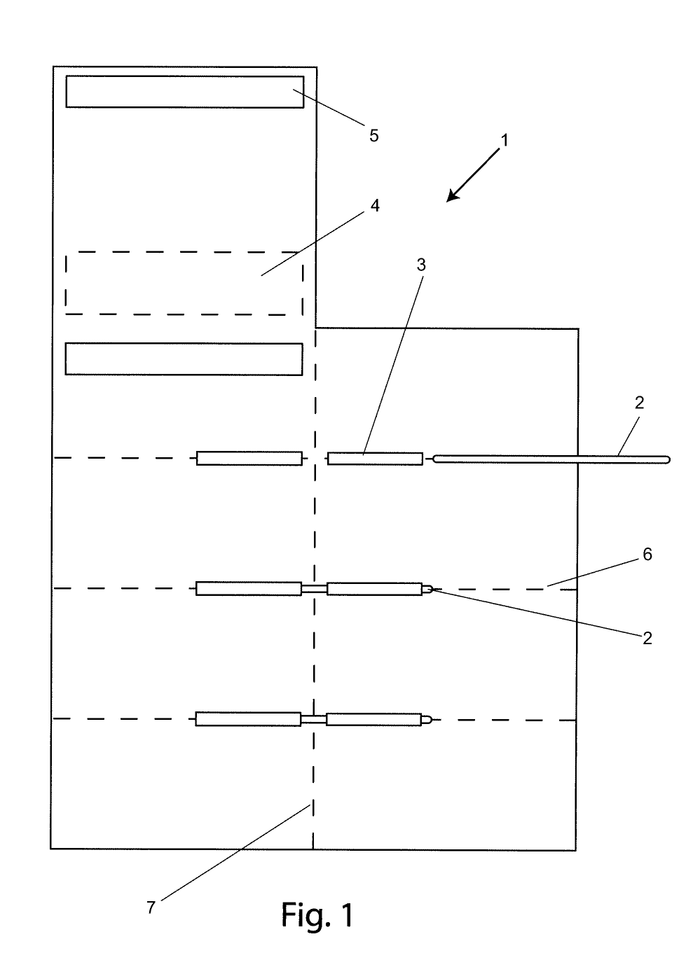

FIG. 2 is a schematic representation of a front view of the transportable solar panel and support system showing the rigid solar cells, a compartment to store a plurality of support rods, and a closure device for securing the compartment, according to an exemplary embodiment.

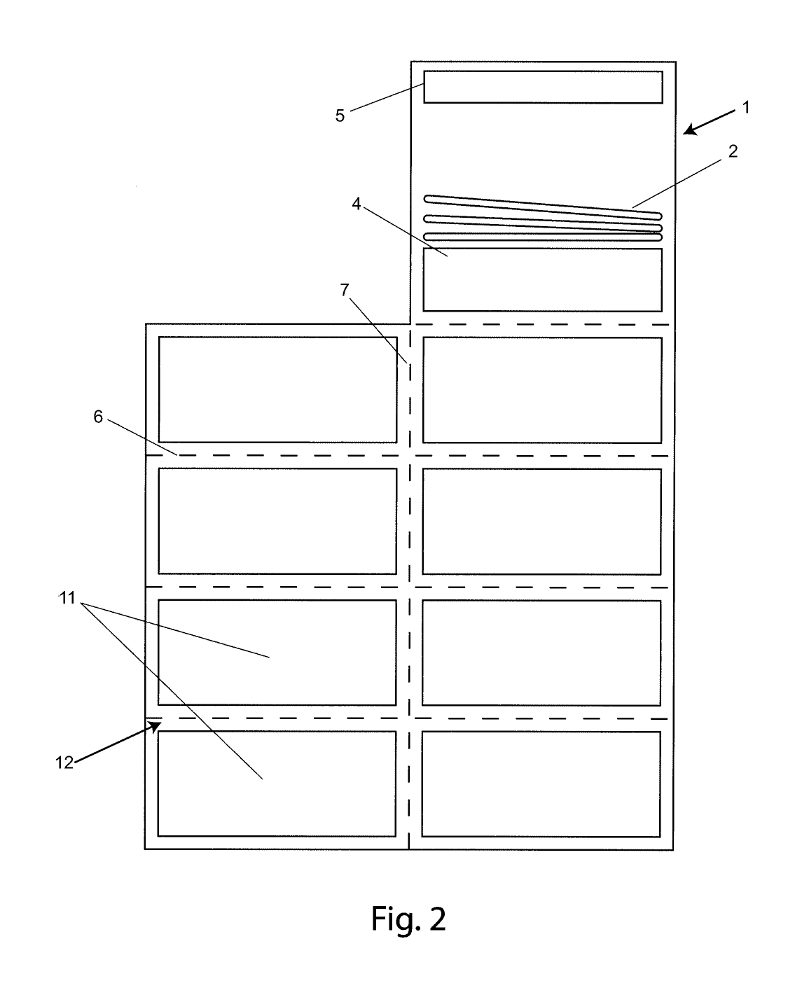

FIG. 3 is a schematic representation of a rear view of a transportable solar panel and support system, showing the use of collapsible support rods, according to an exemplary embodiment.

FIG. 4 is a schematic representation of a rear view of a transportable solar panel and support system, showing the use of support rods in a diagonal arrangement, according to an exemplary embodiment.

### DETAILED DESCRIPTION

Referring to the FIGURES, a transportable solar panel and support system is shown according to an exemplary embodiment to include, as main elements, the following items: a support rod or rods or other similar elongated and rigid members, a flexible or foldable base (e.g. fabric, material, etc.), solar panels coupled to the flexible base, a compartment (e.g. pouch or storage device) with a closure to hold such support rods while not in use (i.e. when the flexible base is folded to a transport position), and receptacles on the flexible base that receive the support rods for rigidifying the flexible base and supporting the solar panels in a deployed position.

There has thus been broadly outlined some of the features of the invention in order that the detailed description thereof may be better understood, and in order that the present contribution to the art may be better appreciated. There are additional features of the invention that will be described hereinafter.

In this respect, before explaining any embodiment of the invention in detail, it is to be understood that the invention is not limited in its application to the details of construction or to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

According to one embodiment, the transportable solar panel and support system is intended to provide a flexible or foldable solar panel support system to provide lightweight and compact support to an otherwise ‘floppy’ foldable array of individual solar panels attached to the base, which when in the deployed position is typically leaned against something such as a rock or tree or the like and still will likely collapse on itself. The ability to rigidify and support the flexible base when in the deployed position is intended to allow the solar panels to more easily and effectively be pointed “normal” to the sun where they achieve the highest efficiencies.

According to another embodiment, the transportable solar panel and support system is intended to provide a foldable solar panel and support system that utilizes collapsible support rods interconnected by an elastic cord, in a manner similar to poles such as are common in tent construction, and which could easily be stored with the storage compartment and then be assembled/expanded to span the desired height of the flexible base to providing a contiguous rigidifying strategy, rather than a segmented rigidifying strategy.

According to another embodiment, the transportable solar panel and support system is intended to provide a foldable solar panel and support system in which such support rods could be positioned various ways such as vertically or diagonally (e.g. such as making and “X” across the back of the panels) or other suitable support pattern.

According to another embodiment, the transportable solar panel and support system is intended to provide a foldable solar panel support system where the receptacles are provided in the form of thin pockets, rings, or perhaps just tucked into pockets on either end of the flexible base, such that the support rods could be slid therethrough.

Referring further to the FIGURES, the components of the invention as shown according to the illustrated embodiment include: a flexible base 1 (e.g. foldable or flexible member such as a sheet of material), a plurality of support members 2 (e.g. support rod, post or other similar securing unit made of a substantially rigid material), receptacles 3 (e.g. fabric loops, pockets or other material or devices designed and positioned to hold the support rod in place on the flexible base), a storage compartment 4 (e.g. pouch, etc.) to hold or store the storage rods when not deployed (i.e. with the flexible base in the folded condition for transport), a closure device 5 (e.g. hook and loop fastener such as Velcro® of the like, snaps, zipper, or other fastening device to close the storage compartment for holding the support rods, a vertical folding axis 6, a horizontal folding axis 7, collapsible support rods 8; diagonally extending support rods 9, diagonally disposed receptacles 10, a plurality of photovoltaic solar cells or panels 11 coupled to the flexible base and spaced apart to form a clearance or flexible gap section 12.

One operational concern associated with such transportable solar panel systems is how to get them pointed “normal” to the sun where they achieve highest efficiencies. For much of the day this is not straight up, but rather at some angle above the horizon. When a foldable, and therefore non-rigid panel is set up, it invariable has difficulty simply being leaned against something such as a rock, or tree, as it will collapse on itself, not having sufficient rigidity throughout its height. The invention according to the illustrated embodiments and as described herein addresses this concern.

As shown in the FIGURES, a plurality of support rods 2 are stored in the compartment 4 of the flexible base 1 as it is folded up for transport. The compartment 4 is fastened shut by closure device 5. In order to deploy the solar panel system, the flexible base 1 is unfolded and the support rods 2 are removed from compartment 4 and inserted at least partially into receptacles 3 (e.g. slid into or through narrow pockets, or loops attached to the back of the flexible base that span one or more of the flexible gap sections 12 between the solar cells. By thus “bridging” gap sections 12, the flexible base 1 is rigidified sufficiently to be leaned upon or against something without collapsing on itself. In the preferred embodiment, the support rods 2 are approximately half the width of the unfolded flexible base, or in other words, the length of the folded base. To sufficiently rigidify the flexible base, it is generally not necessary to add stiffness along the entire height or length, but rather just enough to span the flexible gap sections 12. The inherent rigidity of the solar cells 11 tend to provide the remaining needed stiffness.

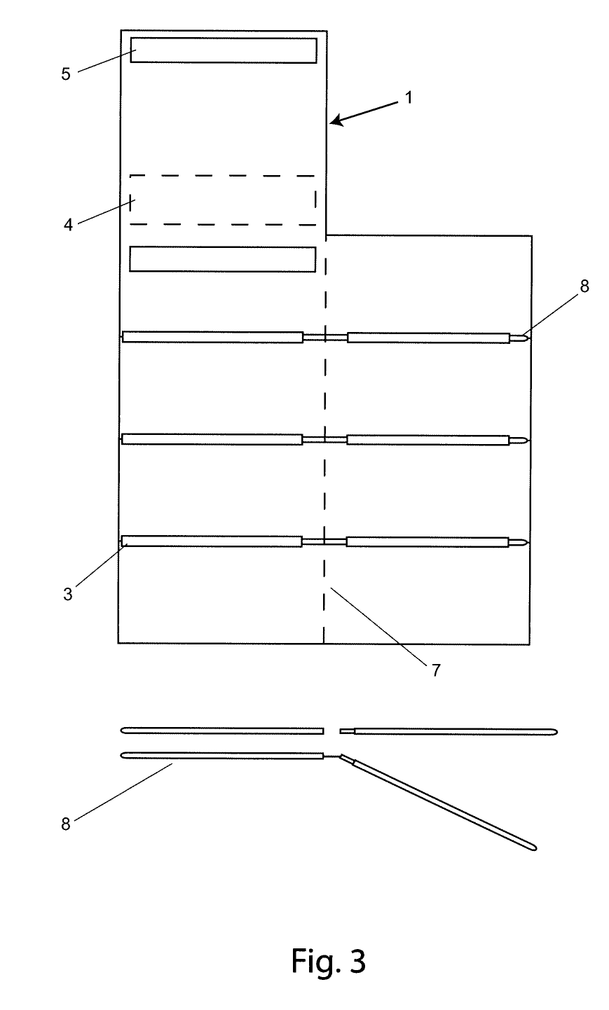

There are other ways this stiffness could be achieved which may have advantages due to various factors such as loose stitching, fabric stretch and other factors that may still make it desirable to have even more stiffness than described above. Referring to FIG. 3, collapsible support rods 8 may be provided having segments that are interconnected by an elastic cord, or that fit within each other end-to-end (such as are common in tent pole construction or the like) could also easily be stored with the storage compartment 4 and then be assembled or expanded to span the entire height of the flexible base 1, thus providing a contiguous rigidifying strategy, rather than a segmented rigidifying strategy.

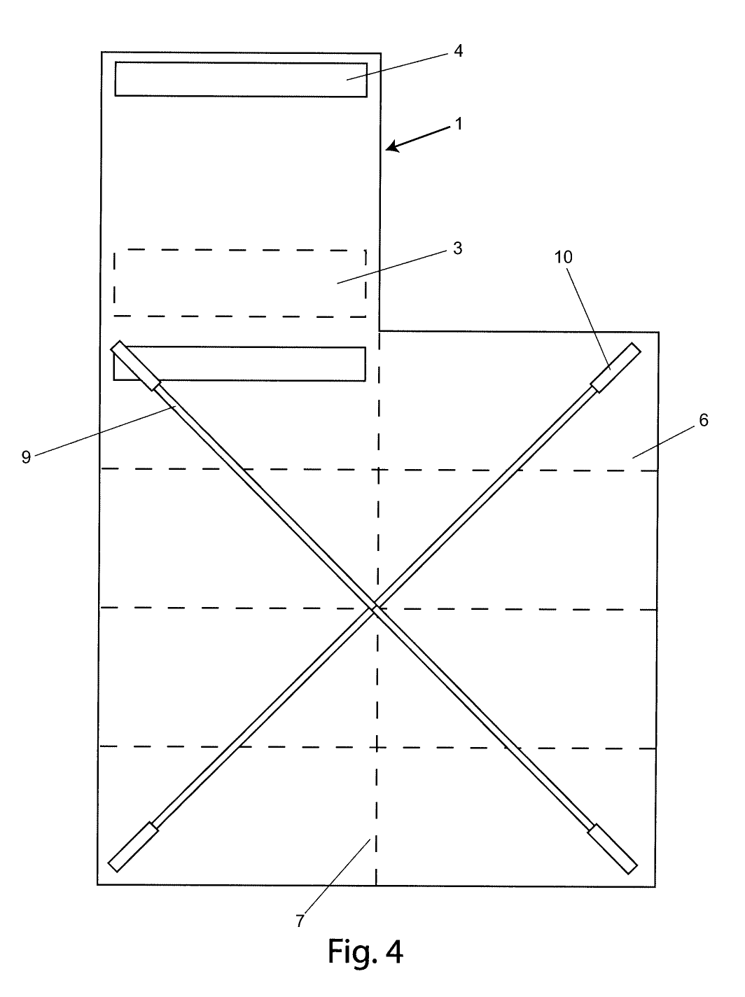

Referring to FIGS. 3 and 4, according to other embodiments the support rods 2 or 8 or 9 may be positioned various ways such as horizontally, vertically or diagonally (such as making and “X” pattern across the flexible base. Also, the rods may be provided in sizes that are longer or shorter than half the width of the unfolded flexible base. Further, the receptacles may be provided as thin pockets, rings, or pockets disposed about the flexible base (e.g. sewn onto or otherwise formed in a sheet of a flexible material, etc.) and configured to receive the support rods (e.g. in a sliding relationship, etc.). According to an alternative embodiment, the solar panels may be provided in a single column or row, such that they can be supported in a deployed position by a single support rod.

According to any preferred embodiment, a transportable solar panel and support system is provided that is quickly and easily assembled by unfolding a flexible base having solar panels attached thereto, and rigidifying the flexible base using self-contained support rods that are configurable in any one of a variety of patterns or configurations, so that the deployed and rigidified system may be oriented toward the sun to obtain higher efficiencies without collapsing. The system is intended to be used by hikers, campers, outdoor enthusiasts and others who wish to harness the full power of their solar panels without the worry of what object they may lean or rest it upon when the reach a desired destination. The support rods may attach to the back of the flexible base and span one or more of the flexible gap sections between the solar panels. The support rods then act as a temporary support for the otherwise flexible (and perhaps flimsy) transportable solar panel.

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It should be noted that the orientation of various elements may differ according to other exemplary embodiments, and that such variations are intended to be encompassed by the present disclosure.

It is also important to note that the construction and arrangement of the systems and methods for installing solar panels as shown in the various exemplary embodiments is illustrative only. Although only a few embodiments of the present inventions have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter disclosed herein. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present invention as defined in the appended claims. The order or sequence of any process or method steps may be varied or re-sequenced according to alternative embodiments. Other substitutions, modifications, changes and omissions may be made in the design, operating conditions and arrangement of the various exemplary embodiments without departing from the scope of the present inventions.

1. A transportable solar panel and support system, comprising:
a sheet of a flexible material having a first side and a second side;
a plurality of photovoltaic solar panels coupled to the first side of the sheet of flexible material, the solar panels spaced apart from one another by gaps to permit the sheet of flexible material to be configured in an unfolded condition so that the solar panels can receive sunlight, and a folded condition where the solar panels are stacked adjacent one another for transport;
a storage compartment disposed on the sheet of flexible material;
a plurality of receptacles disposed on the second side of the sheet of flexible material, at least a portion of the receptacles axially aligned with one another to span one or more of the gaps between the solar panels; and
a plurality of support members; the support members configured to be disposed within the storage compartment when the sheet of flexible material is in the folded condition, and disposed within the receptacles and spanning one or more of the gaps between the solar panels when the sheet of flexible material is in the unfolded condition.

2. The system of claim 1, wherein the support members are substantially parallel to one another when disposed within the receptacles.

3. The system of claim 1, wherein the support members are angled to form an X with respect to one another when disposed within the receptacles.

4. The system of claim 3, wherein the support members comprise hollow tubular support rods.

5. The system of claim 4, wherein at least one support rod is collapsibly coupled to another support rod by an elastic cord.

6. The system of claim 1, wherein the receptacles comprise loops of the flexible material.

7. The system of claim 1, wherein the receptacles comprise pockets in the flexible material.

8. A transportable solar panel and support system, comprising:
a flexible base;
a plurality of photovoltaic solar panels coupled to the flexible base, the solar panels spaced apart from one another by gaps to permit the flexible base to be configured in an unfolded condition so that the solar panels can receive sunlight, and a folded condition where the solar panels are arranged at least partially adjacent to one another;
a storage compartment disposed on the flexible base;
a plurality of receptacles disposed on the flexible base, at least a portion of the receptacles axially aligned with one another to span one or more of the gaps between the solar panels; and
a plurality of support rods movable between a stowed position within the storage compartment when the flexible base is in the folded condition, and a deployed position within the receptacles and spanning one or more of the gaps between the solar panels when the flexible base is in the unfolded condition.

9. The system of claim 8, wherein the support rods are substantially parallel to one another when disposed within the receptacles.

10. The system of claim 8, wherein the support rods are angled with respect to one another when disposed within the receptacles.

11. The system of claim 8, wherein the support rods comprise hollow tubular rods.

12. The system of claim 11, wherein at least one support rod is coupled to another support rod by an elastic cord.

13. The system of claim 8 wherein the flexible base comprises a sheet of fabric material.

14. The system of claim 13, wherein the receptacles comprise loops of the fabric material.

15. The system of claim 13, wherein the receptacles comprise pockets in the fabric material.

16. A method of providing a transportable solar panel and support system, comprising:
providing a flexible base;
coupling a plurality of photovoltaic solar panels to the flexible base, and spacing the solar panels apart from one another by gaps to permit the flexible base to be unfolded so that the solar panels can receive sunlight, and folded where the solar panels are arranged at least partially adjacent to one another;
coupling a storage compartment to the flexible base;
providing a plurality of receptacles on the flexible base, at least a portion of the receptacles axially aligned with one another to span one or more of the gaps between the solar panels; and
providing a plurality of support rods, the support rods being movable between a stowed position within the storage compartment when the flexible base is folded, and a deployed position within the receptacles and spanning one or more of the gaps between the solar panels when the flexible base is unfolded.

17. The system of claim 16, further comprising arranging the receptacles so that the support rods are substantially parallel to one another when disposed within the receptacles.

18. The system of claim 16, further comprising arranging the receptacles so that the support rods are angled with respect to one another when disposed within the receptacles.

19. The system of claim 16, further comprising coupling one or more of the support rods to another support rod by an elastic cord to provide an elongated and collapsible support rod.
